(19) United States
(12) Patent Application Publication
(10) Pub. No.: US 2014/0205702 A1
(43) Pub. Date: Jul. 24, 2014

(54) TEMPLATE, MANUFACTURING METHOD OF THE TEMPLATE, AND POSITION MEASURING METHOD IN THE TEMPLATE

(71) Applicant: KABUSHIKI KAISHA TOSHIBA, Tokyo (JP)

(72) Inventors: Hidenori SATO, Kanagawa (JP); Kentaro OKUDA, Kanagawa (JP); Takeshi FUJIWARA, Kanagawa (JP)

(73) Assignee: KABUSHIKI KAISHA TOSHIBA, Tokyo (JP)

(21) Appl. No.: 13/868,284

(22) Filed: Apr. 23, 2013

Related U.S. Application Data
(60) Provisional application No. 61/756,087, filed on Jan. 24, 2013.

(51) Int. Cl. H01L 21/67; G01B 11/14

(52) U.S. Cl. CPC H01L 21/67011; G01B 11/14
USPC 425/385; 216/44; 356/614

(57) ABSTRACT

According to one embodiment, provided is a template in which a transfer region on which a first pattern to be transferred to a processing target is arranged and a non-transfer region surrounding the transfer region are formed on a principal surface of a template substrate. The template includes a second pattern used to measure deviation of a pattern formed on the template substrate from a design position in at least the transfer region. The second pattern arranged on the transfer region is not transferred to the processing target when a transfer to the processing target is performed through an imprint material.

### CROSS-REFERENCE TO RELATED APPLICATIONS

This application is based upon and claims the benefit of priority from U.S. Provisional Application No. 61/756,087, filed on Jan. 24, 2013; the entire contents of which are incorporated herein by reference.

### FIELD

Embodiments described herein relate generally to a template, a manufacturing method of the template, and a position measuring method in the template.

### BACKGROUND

In a technique of manufacturing a semiconductor device including various kinds of many semiconductor elements such as transistors, a pattern scaling technique for increasing a degree of integration has been used. For further scaling, it is a critical issue to improve the accuracy of overlapping between layers. For this reason, a technique for improving management of a pattern position accuracy of a photomask or a nanoimprint template which is a factor of a variation has been developed.

Examples of a method of performing management of the position accuracy of a photomask includes (1) a method of directly measuring a device pattern and (2) a method of measuring a measurement pattern that does not function as a device. Meanwhile, in the optical lithography, a pattern on a photomask is transferred to a substrate at ¼ times, whereas in the nanoimprint lithography, a pattern on a photomask is transferred to a substrate at the same size, a device pattern has the size of a position measurement limit or less (the size of 80 nm or less). For this reason, there is a problem in that it is difficult to perform position measurement through a pattern position measuring device.

Further, when a measurement pattern is arranged, in a device having a high degree of integration in a chip such as memory devices, when the measurement pattern is transferred to the substrate, a problem occurs in a device operation. For this reason, the measurement pattern is arranged in a region (kerf) outside a chip. Thus, there is a problem in that under this condition, it is difficult to measure the position in a chip, the number of measurement patterns arranged in a template is restricted, and it is difficult to perform multi-point measurement.

### BRIEF DESCRIPTION OF THE DRAWINGS

FIGS. 1A to 1C are diagrams schematically illustrating an example of a structure of a non-completed nanoimprint template according to a first embodiment.

FIGS. 2A to 2C are diagrams schematically illustrating an example of a structure of a completed nanoimprint template according to the first embodiment.

FIGS. 3A to 3E are cross-sectional views schematically illustrating an example of a process of a template manufacturing method according to the first embodiment.

FIG. 4 is a flowchart illustrating an example of a process of a template manufacturing method according to the first embodiment.

FIGS. 5A and 5B are diagrams schematically illustrating an example of a structure of a non-completed nanoimprint template according to a second embodiment.

FIGS. 6A and 6B are diagrams schematically illustrating an example of a structure of a completed nanoimprint template according to the second embodiment.

FIGS. 7A to 7E are cross-sectional views schematically illustrating an example of a process of a template manufacturing method according to the second embodiment.

FIG. 8 is a flowchart illustrating an example of a process of a template manufacturing method according to the second embodiment.

FIGS. 9A and 9B are diagrams schematically illustrating an example of a structure of a non-completed nanoimprint template according to a third embodiment.

FIGS. 10A and 10B are diagrams schematically illustrating an example of a structure of a completed nanoimprint template according to the third embodiment.

### DETAILED DESCRIPTION

In general, according to one embodiment, provided is a template in which a transfer region on which a first pattern to be transferred to a processing target is arranged and a non-transfer region surrounding the transfer region are formed on a principal surface of a template substrate. The template includes a second pattern used to measure deviation of a pattern formed on the template substrate from a design position in at least the transfer region. The second pattern arranged on the transfer region is not transferred to the processing target when a transfer to the processing target is performed through an imprint material.

Hereinafter, a template, a manufacturing method of the template, and a position measuring method in the template according to exemplary embodiments will be described in detail with reference to the accompanying drawings. The present invention is not limited these exemplary embodiments.

### First Embodiment

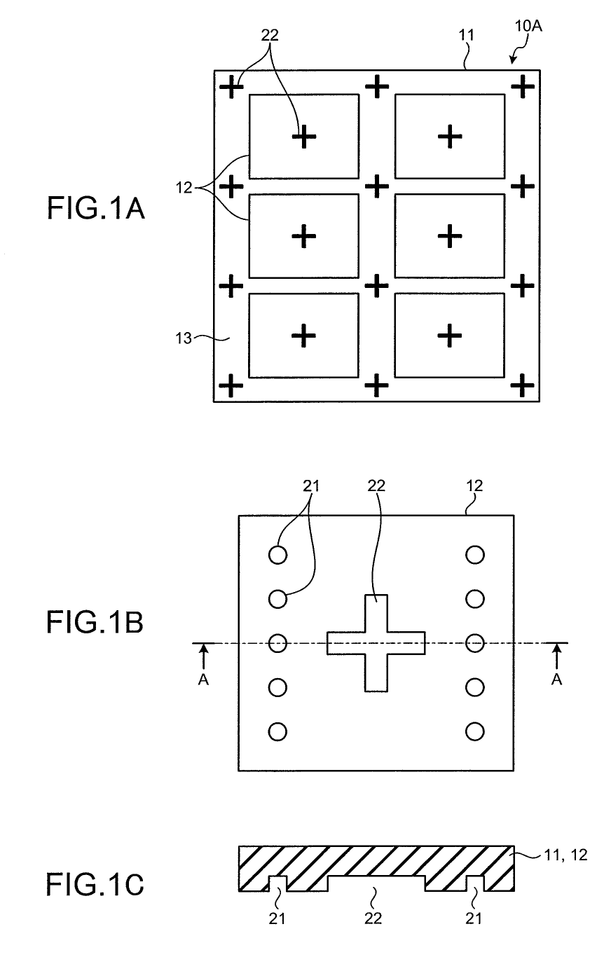

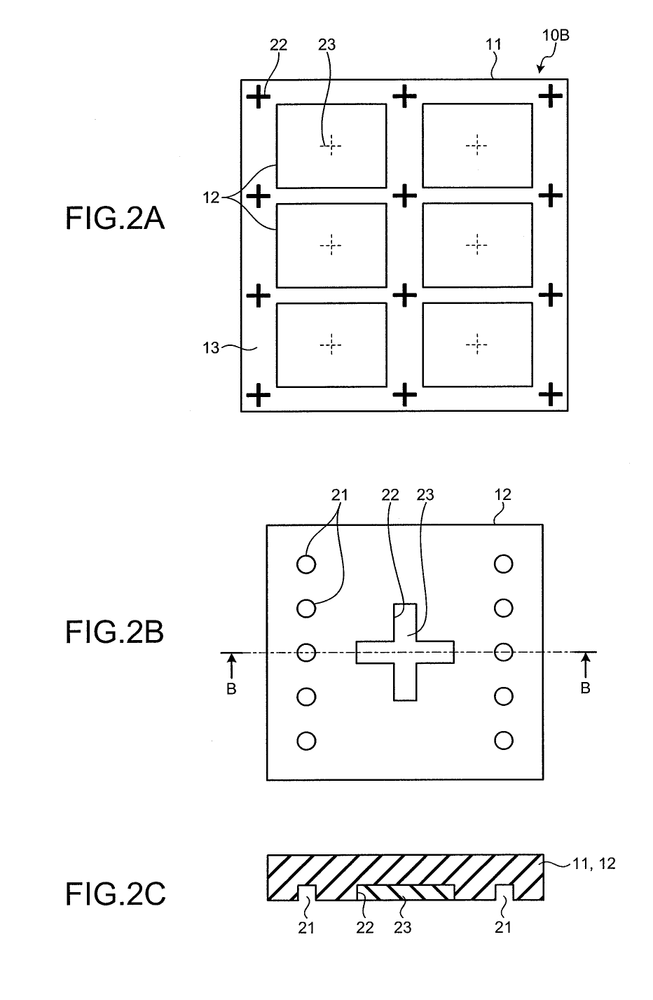

FIGS. 1A to 1C are diagrams schematically illustrating an example of a structure of a non-completed nanoimprint template according to a first embodiment. FIGS. 2A to 2C are diagrams schematically illustrating an example of a structure of a completed nanoimprint template according to the first embodiment. FIGS. 1A and 2A are plan views schematically illustrating the entire nanoimprint template, FIGS. 1B and 2B are plan views illustrating enlarged parts of a chip region of FIGS. 1A and 2A, respectively, FIG. 1C is a cross-sectional view taken along line A-A of FIG. 1B, and FIG. 2C is a cross-sectional view taken along line B-B of FIG. 2B.

As will be described below, in the template according to the first embodiment, deviation is measured using a measurement pattern 22 in the process of manufacturing the template illustrated in FIGS. 1A to 1C, and then a template, in which some measurement patterns 22 are removed, illustrated in FIGS. 2A to 2C is used for a subsequent semiconductor manufacturing process as a master template. In the following, a template illustrated in FIGS. 1A to 1C is referred to as a “non-completed template 10A,” and a template illustrated in FIGS. 2A to 2C is referred to as a “completed template 10B.”

The non-completed template 10A has a structure in which a plurality of transfer regions 12 are defined on a template substrate 11 made of quartz or the like as illustrated in FIG. 1A. For example, the transfer region 12 is a region corresponding to a chip, and a device pattern 21 used to form a device is arranged on the transfer region 12. Further, a non-transfer region called a kerf 13 to be removed by a dicing process is defined surrounding the transfer region 12.

The non-completed template 10A includes a plurality of patterns 22 used to measure a degree by which a pattern actually formed on the template substrate 11 is deviated on design data of a template. In the first embodiment, the measurement pattern 22 is formed not only the kerf 13 but also the transfer region 12 as in a general template. The measurement pattern 22 has a concave shape caved into the template substrate 11. For example, the measurement pattern 22 has a cross shape and has the size of 80 nm or more that can be measured (optically recognized) by a pattern position measuring device. For example, as the measurement pattern 22, illustrated is a cross pattern in which two rectangular patterns having the length of 1 μm and the width of 300 nm change their directions at 90° in the plane of the template substrate 11 and intersect with each other near the center of each other. In this example, the device pattern 21 has the size of 50 nm. In the transfer region 12, the measurement pattern 22 is formed on a region in which the device pattern 21 is not arranged.

The non-completed template 10A illustrated in FIGS. 1A to 1C is used for position measurement in the process of manufacturing the template. After position measurement is performed, at least the measurement pattern 22 within the transfer region 12 is removed. The removed completed template 10B is illustrated in FIGS. 2A to 2C.

As illustrated in FIG. 2A, in the completed template 10B, the measurement pattern 22 in the kerf 13 is the same as in the non-completed template 10A, but the measurement pattern 22 in the transfer region 12 is moved from the non-completed template 10A. Here, since the measurement pattern 22 in the transfer region 12 has the concave shape, the measurement pattern 22 is removed such that a embedded layer 23 is embedded in the concave-shaped measurement pattern 22 as illustrated in FIGS. 2B and 2C.

The embedded layer 23 is not particularly limited. For example, as the embedded layer 23, a layer having the same refractive index as the template substrate 11 may be used, and a layer having a different refractive index from the template substrate 11 may be used. When the layer having the same refractive index as the template substrate 11 is embedded, it is difficult (hard) to optically recognize the measurement pattern 22 in the completed template 10B. Meanwhile, when the layer having the different refractive index from the template substrate 11 is embedded, the measurement pattern 22 can be recognized even in the completed template 10B. When an optically recognizable material is used as described above, the embedded layer 23 embedded in the measurement pattern 22 can be used as a strain measurement pattern used to measure strain accumulated on the completed template 10B.

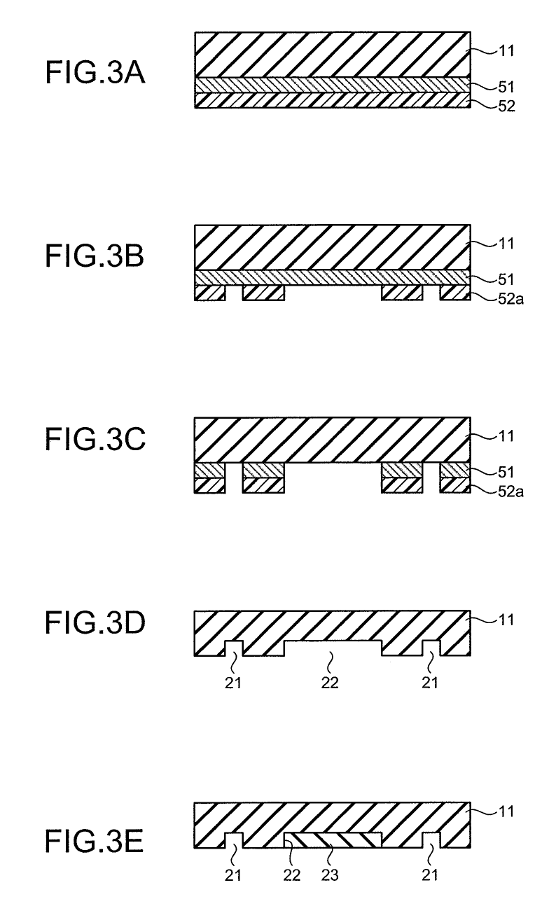

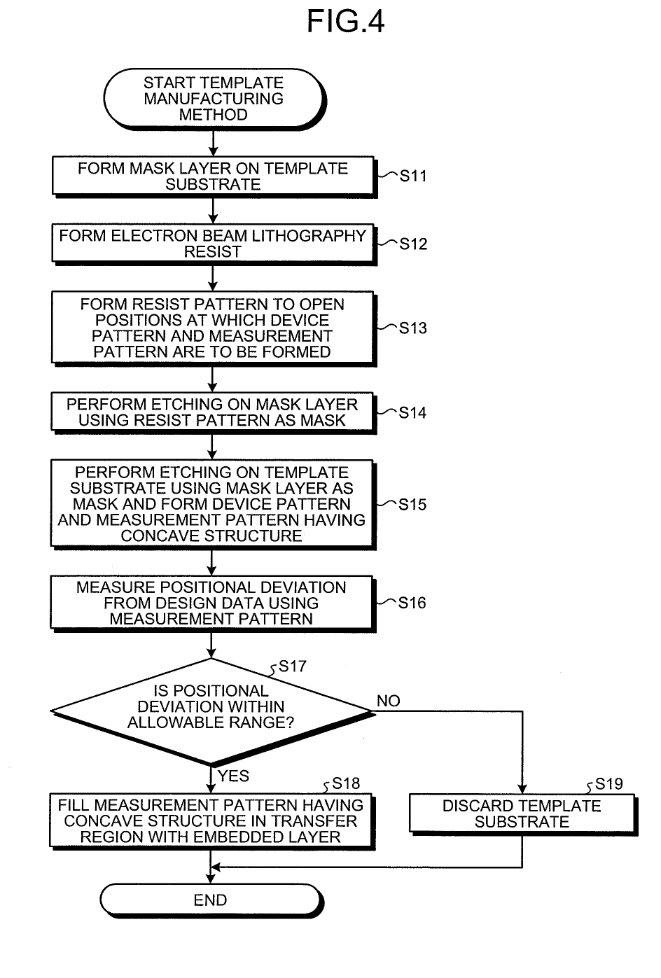

Next, the template manufacturing method will be described. FIGS. 3A to 3E are cross-sectional views schematically illustrating an example of a process of a template manufacturing method according to the first embodiment, and FIG. 4 is a flowchart illustrating the example of the process of the template manufacturing method according to the first embodiment.

First of all, a mask layer 51 is formed on a principal surface of the template substrate 11 as illustrated in FIG. 3A (step S11). For example, a quartz substrate may be used as the template substrate 11, and a Cr layer formed at the thickness of 20 nm by a method such as the sputtering technique may be used as the mask layer 51. Then, an electron beam lithography resist 52 is formed on the mask layer 51 by a method such as the spin coating technique (step S12). For example, the electron beam lithography resist 52 has the thickness of 30 nm.

Thereafter, a resist pattern 52a used to form the device pattern 21 and the measurement pattern 22 is formed by light exposure and development using an electron beam lithography device as illustrated in FIG. 3B (step S13). Here, the resist pattern 52a is formed to open a region on which the device pattern 21 and the measurement pattern 22 are to be formed. For example, the device pattern 21 may have the width of 50 nm. A pattern in which two rectangular patterns having the width 300 nm and the length of 1 μm are crossed in the form of a cross near the center thereof can be formed as the measurement pattern 22. The device pattern 21 is formed on each transfer region 12, and the measurement pattern 22 is formed at predetermined positions of the kerf 13 and the transfer region 12. Further, in the transfer region 12, the measurement pattern 22 is adjusted not to overlap the device pattern 21.

Then, the mask layer 51 is etched by dry etching using the resist pattern 52a as a mask, and thus the device pattern 21 and the measurement pattern 22 are transferred to the mask layer 51 as illustrated in FIG. 3C (step S14).

Thereafter, the template substrate 11 is etched up to a predetermined depth by dry etching using the patterned mask layer 51 as a mask as illustrated in FIG. 3D (step S15). For example, the etching depth may be 30 nm. As a result, the device pattern 21 with the concave structure having the width 50 nm and the depth of 30 nm is formed on the transfer region 12, and a measurement pattern 22 with the cross-shaped concave structure in which two rectangular patterns having the width of 300 nm, the length of 1 μm, and the depth of 30 nm are crossed at 90° is formed on the kerf 13 and the transfer region 12, and thus the non-completed template 10A is consequently obtained.

Then, positional deviation from the design data is measured using the measurement pattern 22, that is, the measurement pattern 22 of the template substrate 11, through a pattern position measuring device (step S16). Then, it is determined whether or not the positional deviation is within an allowable range having on influence on a characteristic of a product to be manufactured even when a subsequent process is continued using the corresponding template (step S17).

When it is determined that the positional deviation is within the allowable range (Yes in step S17), the embedded layer 23 is embedded in the measurement pattern 22 with the concave structure in the transfer region 12 as illustrated in FIG. 3E (step S18). For example, C may be locally deposited in the concave structure using ion beams to form the embedded layer 23. Consequently, the embedded layer 23 that has the different refractive index from the template substrate 11 and can be optically recognized is embedded in the concave structure of the measurement pattern 22 in the transfer region 12. Thus, the completed template 10B including the template substrate 11 in which the concave structure of the measurement pattern 22 in the transfer region 12 is filled is obtained, and the template manufacturing method ends.

Thereafter, the completed template 10B is used for manufacturing of a semiconductor device or manufacturing of a daughter template. Specifically, a processing target which is a wafer on which a semiconductor device is to be manufactured or a daughter template is coated with a hardening resin (an imprint material) curable by light (ultraviolet (UV) light or the like) or heat, and the completed template 10B is pressed into the processing target while irradiating light or applying heat, and thus the hardening resin is cured. Thereafter, the completed template 10B is removed, and a process of processing (etching) the processing target using the cured hardening resin as a mask is performed.

However, when it is determined in step S17 that the positional deviation is not within the allowable range (No in step S17), it is difficult to use the template as a product, and thus the template is discarded (step S19), and the template manufacturing process ends.

In the first embodiment, when the template is manufactured, the concave-shaped measurement pattern 22 is formed not only on the kerf 13 but also on the transfer region 12, the positional deviation of the design position of the pattern is measured using the measurement pattern 22, and then concave-shaped measurement pattern 22 is filled. Thus, compared to the example in which the measurement pattern 22 is arranged only on the kerf 13, measurement points of the positional deviation are increased, and thus there is an effect by which the template can be manufactured with a high degree of accuracy. Further, since the measurement pattern 22 formed on the transfer region 12 is filled, when a device is actually manufactured, the measurement pattern 22 is not transferred onto the processing target. Consequently, there is an effect by which the template can be manufactured with a high degree of accuracy without affecting a device.

In addition, as the measurement pattern 22 of the transfer region 12 is filled with the embedded layer 23 which is optically recognizable in the template, there is an effect by which when a product is manufactured using the template, the measurement patterns 22 on the kerf 13 and the transfer region 12 can be used for measurement of strain or the like accumulated in the template.

### Second Embodiment

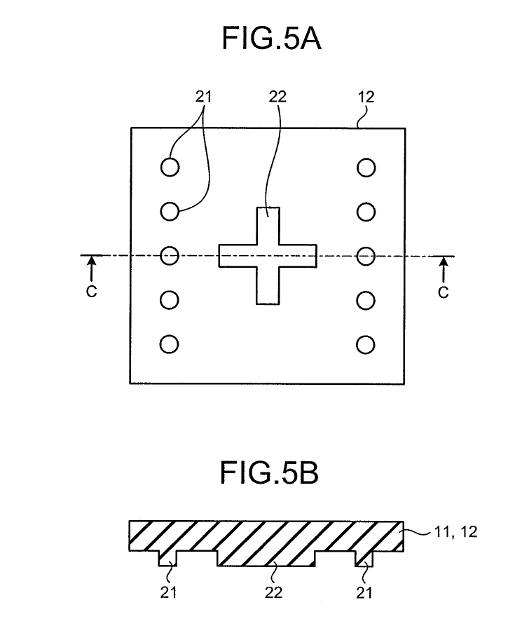

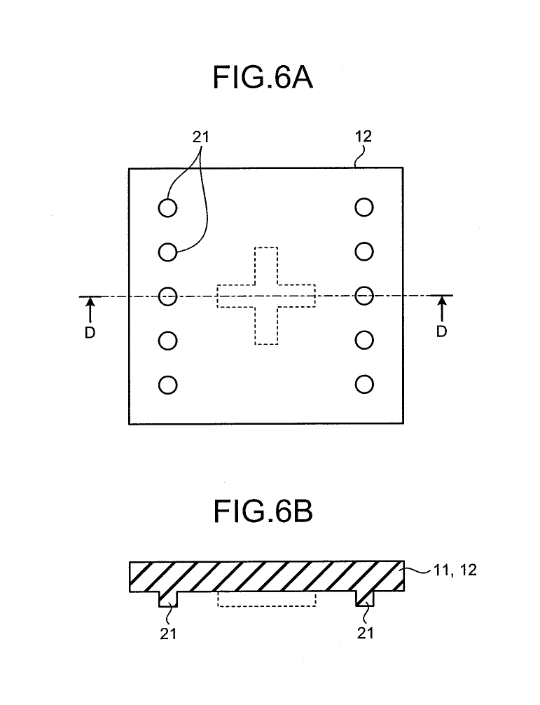

FIGS. 5A and 5B are diagrams schematically illustrating an example of a structure of a non-completed nanoimprint template according to a second embodiment. FIGS. 6A and 6B are diagrams schematically illustrating an example of a structure of a completed nanoimprint template according to the second embodiment. FIGS. 5A and 6A are plan views illustrating enlarged parts of a chip region of FIGS. 1A and 2A, respectively, FIG. 5B is a cross-sectional view taken along line C-C of FIG. 5A, and FIG. 6B is a cross-sectional view taken along line D-D of FIG. 6A.

In the second embodiment, similarly to the first embodiment, the non-completed template 10A includes the measurement patterns 22 on the kerf 13 and the transfer region 12, and the completed template 10B includes the measurement pattern 22 only on the kerf 13, and the measurement pattern 22 on the transfer region 12 is removed.

In the second embodiment, the device pattern 21 and the measurement pattern 22 have the convex shape as illustrated in FIGS. 5A and 5B. When the positional deviation measurement in the non-completed template 10A ends, the measurement pattern 22 on the transfer region 12 is etched to be removed. Consequently, the measurement pattern 22 is not presented on the transfer region 12 of the completed template 10B as illustrated in FIGS. 6A and 6B. When a product is manufactured using the completed template 10B, since the measurement pattern 22 is not presented on the transfer region 12, the measurement pattern 22 does not adversely affect the device on the transfer region 12. In FIGS. 6A and 6B, the removed measurement pattern 22 is represented by a dotted line.

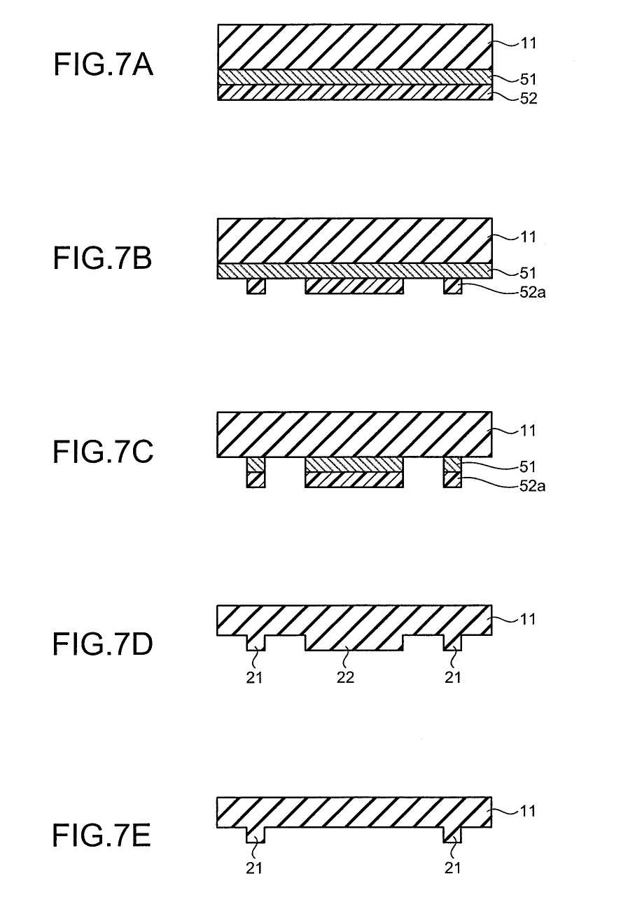

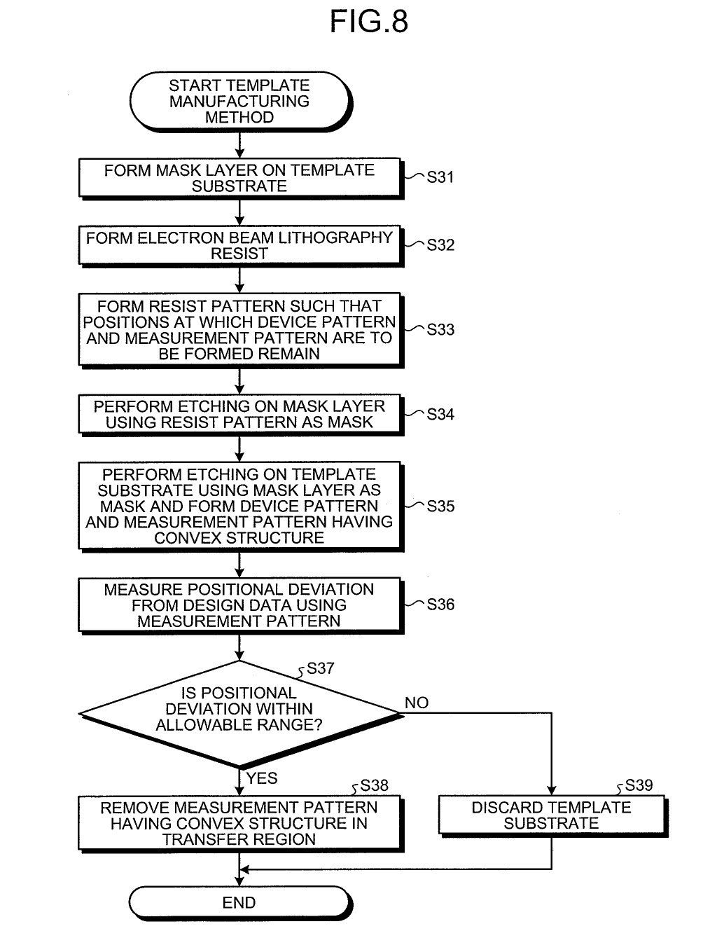

Next, the template manufacturing method will be described. FIGS. 7A to 7E are cross-sectional views schematically illustrating an example of a process of a template manufacturing method according to the second embodiment, and FIG. 8 is a flowchart illustrating the example of the process of the template manufacturing method according to the second embodiment.

First of all, a mask layer 51 is formed on a principal surface of the template substrate 11 as illustrated in FIG. 7A (step S31). For example, a quartz substrate may be used as the template substrate 11, and a Cr layer formed at the thickness of 20 nm by a method such as the sputtering technique may be used as the mask layer 51. Then, an electron beam lithography resist 52 is formed on the mask layer 51 by a method such as the spin coating technique (step S32). For example, the electron beam lithography resist 52 has the thickness of 30 nm.

Thereafter, a resist pattern 52a used to form the device pattern 21 and the measurement pattern 22 is formed by light exposure and development using an electron beam lithography device as illustrated in FIG. 7B (step S33). Here, the resist pattern 52a is formed such that a region on which the device pattern 21 and the measurement pattern 22 are to be formed remains. For example, the device pattern 21 may have the width of 50 nm. A pattern in which two rectangular patterns having the width 300 nm and the length of 1 μm are crossed in the form of a cross near the center thereof can be formed as the measurement pattern 22. The device pattern 21 is formed on each transfer region 12, and the measurement pattern 22 is formed at predetermined positions of the kerf 13 and the transfer region 12. Further, in the transfer region 12, the measurement pattern 22 is adjusted not to overlap the device pattern 21.

Then, the mask layer 51 is etched by dry etching using the resist pattern 52a as a mask, and thus the device pattern 21 and the measurement pattern 22 are transferred to the mask layer 51 as illustrated in FIG. 7C (step S34). Consequently, the mask layer 51 remains at the position at which the device pattern 21 and the measurement pattern 22 are to be formed.

Thereafter, the template substrate 11 is etched up to a predetermined depth by dry etching using the patterned mask layer 51 as a mask as illustrated in FIG. 7D (step S35). For example, the etching depth may be 30 nm. As a result, the device pattern 21 with the convex structure having the width 50 nm and the depth of 30 nm is formed on the transfer region 12, and a measurement pattern 22 with the cross-shaped convex structure in which two rectangular patterns having the width of 300 nm, the length of 1 μm, and the depth of 30 nm are crossed at 90° is formed on the kerf 13 and the transfer region 12, and thus the non-completed template 10A is consequently obtained.

Then, positional deviation from the design data is measured using the measurement pattern 22, that is, the measurement pattern 22 of the template substrate 11, through a pattern position measuring device (step S36). Then, it is determined whether or not the positional deviation is within an allowable range having on influence on a characteristic of a product to be manufactured even when a subsequent process is continued using the corresponding template (step S37).

When it is determined that the positional deviation is within the allowable range (Yes in step S37), the measurement pattern 22 in the transfer region 12 is removed as illustrated in FIG. 7E, (step S38). For example, the non-completed template 10A is coated with a resist, light exposure and development are performed to open the measurement pattern 22 of the transfer region 12. Thereafter, the measurement pattern 22 of the transfer region 12 is etched and removed by dry etching. Consequently, the completed template 10B including the template substrate 11 from which the convex structure of the measurement pattern 22 in the transfer region 12 is removed is obtained, and the template manufacturing method ends. Thereafter, the completed template 10B is used for manufacturing of a semiconductor device or manufacturing of a daughter template as described in the first embodiment.

However, when it is determined in step S37 that the positional deviation is not within the allowable range (No in step S37), it is difficult to use the template as a product, and thus the template is discarded (step S39), and the template manufacturing process ends.

In the second embodiment, the template is formed such that the device pattern 21 and the measurement pattern 22 have the convex structure, and the measurement pattern 22 is formed on both the kerf 13 and the transfer region 12. Further, after positional deviation measurement using the measurement pattern 22 ends, the measurement pattern 22 on the transfer region 12 is removed by etching, and a semiconductor device is manufactured using the template. Thus, there is an effect by which when the template is manufactured, the positional deviation of the pattern formed on the template can be precisely measured using many measurement patterns 22. In addition, there is an effect by which when a semiconductor device is manufactured, since the measurement pattern 22 is not present on the transfer region 12, a device characteristic is not adversely affected.

### Third Embodiment

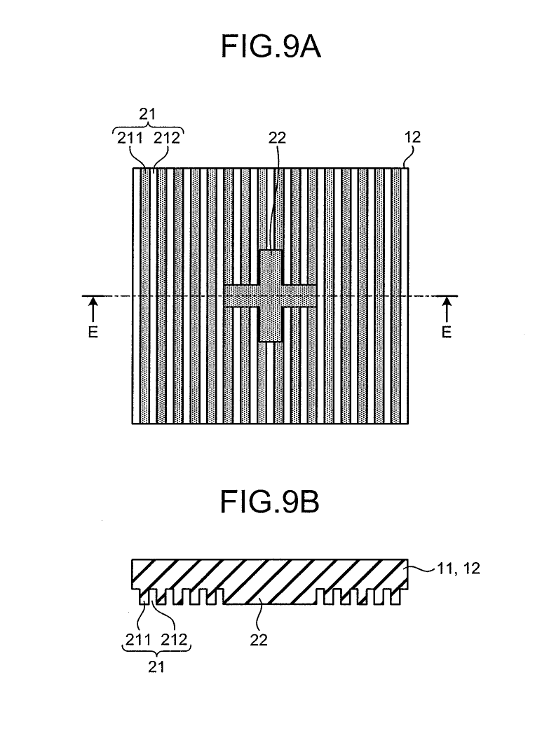

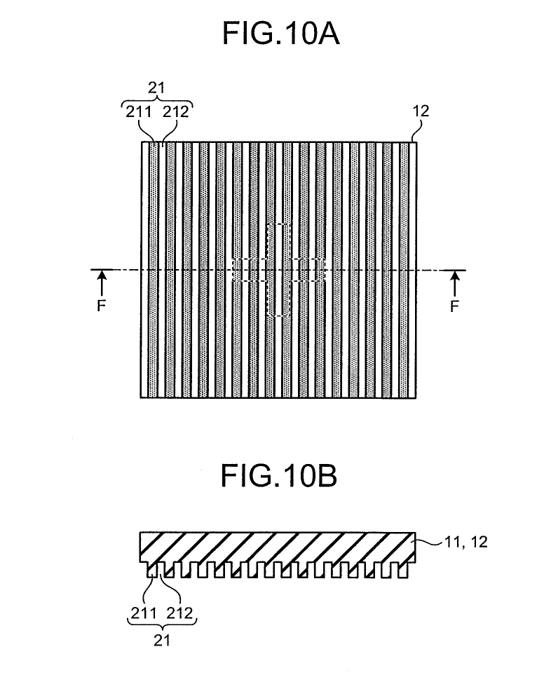

FIGS. 9A and 9B are diagrams schematically illustrating an example of a structure of a non-completed nanoimprint template according to a third embodiment. FIGS. 10A and 10B are diagrams schematically illustrating an example of a structure of a completed nanoimprint template according to the third embodiment. FIGS. 9A and 10A are plan views illustrating enlarged parts of a chip region of FIGS. 1A and 2A, respectively, FIG. 9B is a cross-sectional view taken along line E-E of FIG. 9A, and FIG. 10B is a cross-sectional view taken along line F-F of FIG. 10A.

In the third embodiment, the device pattern 21 of the transfer region 12 is a pattern of a line-and-space form. The device pattern 21 and the measurement pattern 22 have a convex shape as illustrated in FIGS. 9A and 9B. The line-and-space pattern is a pattern in which the line pattern 211 and the space pattern 212 are alternately arranged in a direction perpendicular to an extending direction of the line pattern 211. For example, each of the line pattern 211 and the space pattern 212 has the width of 20 nm.

Further, the measurement pattern 22 is patterned into a pattern of a cross shape described in the first embodiment or the second embodiment using the line-and-space pattern. In other words, the non-completed template 10A has the structure in which the measurement pattern 22 is embedded (overlaps) in the line-and-space pattern.

When the positional deviation measurement in the non-completed template 10A ends, the measurement pattern 22 on the transfer region 12 is removed by etching. In other words, the pattern embedded between the line patterns 211 is removed. Consequently, as illustrated in FIGS. 10A and 10B, on the transfer region 12 of the completed template 10B, the measurement pattern 22 is not present, but only the line-and-space pattern remains. When a product is manufactured using the completed template 10B, since the measurement pattern 22 is not presented on the transfer region 12, the measurement pattern 22 does not adversely affect the device on the transfer region 12. The remaining portions are similar in structure to the second embodiment, and a description thereof will not be made.

The template manufacturing method is basically similar to the second embodiment except the process of removing the measurement pattern 22. In this regard, the process of removing the measurement pattern will be described below.

When it is determined in step S37 of FIG. 8 of the second embodiment that the positional deviation is within the allowable range (Yes in step S37), the measurement pattern 22 in the transfer region 12 is removed. At this time, for example, a template constitutional material of a region to be embedded between the line patterns 211 of the line-and-space pattern, that is, a region which is original the space pattern 212 is removed by a mask correcting method (a mask correcting device) using a focused ion beam (hereinafter, referred to as an “FIB”) or an electron beam (hereinafter, referred to as an “EB”).

When removal using the FIB is performed, an ion beam such as a Ga ion is irradiated to the removal region, and the template constitutional material is removed by the sputtering technique. Alternatively, an etching gas is introduced, the etching gas is excited by the ion beam, and the template constitutional material of the removal region is selectively etched. When the removal using the EB is performed, an etching gas is introduced, the etching gas is excited by the electron beam, and the template constitutional material of the removal region is selectively etched. The correction position accuracy of the FIB is about 3 to 4 nm, the correction position accuracy of the EB is about 2 to 3 nm, and thus even a fine line-and-space pattern can be locally etched. As a result, obtained is the completed template 10B including the template substrate 11 in which the portion (the convex structure) presented in the space pattern 212 of the line-and-space pattern of the measurement pattern 22 in the transfer region 12 is removed.

In the third embodiment, the non-completed template 10A has the structure in which the measurement pattern 22 overlaps the device pattern 21 in the transfer region 12, and after the positional deviation measurement using the measurement pattern 22 ends, only the measurement pattern 22 is removed without breaking up the device pattern 21. Thus, in addition to the effect of the second embodiment, it is possible to obtain an effect by which even when the pattern such as the line-and-space pattern is formed on the whole transfer region 12, the measurement pattern 22 is formed in the transfer region 12, and the measurement pattern 22 in the transfer region 12 can be removed in the completed template 10B.

Further, in the first to third embodiments, the position deviation measurement is performed after the device pattern 21 and the measurement pattern 22 are formed in the template. However, the pattern used to form the measurement pattern in the developed resist pattern 52a or the pattern used to form the measurement pattern in the patterned mask layer 51 may be measured. In these cases, when it is determined that the positional deviation is not within the allowable range, the electron beam lithography resist 52 or the mask layer 51 may be removed, the mask layer 51 and the resist pattern 52a may be formed on the same template substrate 11 again, and then the same process may be performed. When the positional deviation measurement is measured using the pattern used to form the measurement pattern 22 is performed and the position deviation is not within the allowable range, since the template substrate 11 is not processed yet, the electron beam lithography resist 52 or the mask layer 51 has only to be removed, and the template substrate 11 need not be discarded. Consequently, there is an effect by which the manufacturing cost of the template can be reduced.

In the above description, the measurement pattern 22 on the transfer region 12 is removed, but the measurement pattern 22 on the kerf 13 may be also removed. In addition, the above description has been described in connection with the example in which a single measurement pattern 22 is arranged on the transfer region 12, but a plurality of measurement patterns 22 may be arranged.

Further, in the above description, although the measurement pattern 22 is formed in transfer region 12 and the non-transfer region (kerf 13), the measurement pattern 22 may be formed in at least the transfer region 12.

### Fourth Embodiment

In the first to third embodiments, the positional deviation measurement and the template determining method using the same have not been described in detail. As described in the above embodiment, as the measurement pattern 22 is arranged on the transfer region 12 as well as the kerf 13, compared to the related art in which the measurement pattern 22 is arranged only on the kerf 13 and the positional deviation measurement is performed, the number of measurement points increases, and the template can be managed with a high degree of accuracy.

Here, the process of measuring the positional deviation of the template will be described. The positional deviation measurement using the measurement pattern 22 is performed using the measurement pattern 22 on the kerf 13 and the measurement pattern 22 on the transfer region 12, but this measurement can be performed using various methods. For example, the measurement patterns 22 on the kerf 13 and the transfer region 12 may be simultaneously measured. Alternatively, the measurement pattern 22 on the kerf 13 may be first measured, and then the measurement pattern 22 on the transfer region 12 may be measured.

(1) A case in which the measurement patterns 22 on the kerf 13 and the transfer region 12 are simultaneously measured.

In this case, it is determined whether or not the positional deviation is within the allowable range using the positional deviation measurement at all measured points (the measurement patterns 22).

(2) A case in which the measurement pattern 22 on the kerf 13 is first measured, and then the measurement pattern 22 on the transfer region 12 is measured.

In this case, the positional deviation measurement is first performed using the measurement pattern 22 on the kerf 13, and a first determination on whether or not the positional deviation is within the allowable range. Here, when it is determined that the positional deviation is not within the allowable range, the process of discarding template is performed, and a second determination which will be described below is not performed. However, when it is determined that the positional deviation is within the allowable range, the positional deviation measurement is further performed using the measurement pattern 22 on the transfer region 12, and the second determination on whether or not the positional deviation is within the allowable range is performed. Here, when it is determined that the positional deviation is not within the allowable range, the process of discarding template is performed, whereas when it is determined that the positional deviation is within the allowable range, the template can be used as the completed template 10B.

In other words, when the positional deviation on the kerf 13 is within the allowable range but the positional deviation on the transfer region 12 is not within the allowable range, the template is discarded.

Further, in this process, the value of the allowable range used in the first determination may differ from the value of the allowable range used in the second determination. For example, the values of the allowable ranges may be set such that a rough determination is performed as the first determination, and an accurate determination is performed as the second determination. As the two-step determination is performed, the accurate determination whether or not the template is to be discarded can be precisely performed, and even when the number of measurement points increases, the determination process on whether or not the template is to be discarded can be effectively performed.

According to the fourth embodiment, the first determination of measuring the measurement pattern 22 on the kerf 13 and determining whether or not the positional deviation is within the allowable range using the measurement result and the second determination of determining whether or not the positional deviation is within the allowable range using the measurement pattern 22 on the transfer region 12 when it is determined in the first determination that the position deviation is within the allowable range are performed in order. Consequently, since the second determination is not performed on the template that is determined in the first determination not to be within the allowable range, there is an effect by which the determination process can be effectively performed. In addition, there is an effect by which the accurate determination can be performed on whether or not the template can be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template in which a transfer region on which a first pattern to be transferred to a processing target is arranged and a non-transfer region surrounding the transfer region are arranged on a principal surface of a template substrate, the template comprising:
a second pattern used to measure deviation of a pattern formed on the template substrate from a design position in at least the transfer region,
wherein the second pattern arranged on the transfer region is not transferred to the processing target when a transfer to the processing target is performed through an imprint material.

2. The template according to claim 1, wherein the second pattern has an optically recognizable size.

3. The template according to claim 1, wherein
the first pattern and the second pattern have a concave structure on the principal surface of the template substrate, and
when the transfer is performed, the second pattern arranged on the transfer region is filled with a embedded layer such that the second pattern is not transferred to the processing target.

4. The template according to claim 3, wherein the embedded layer is made of a material having a refractive index different from the template substrate.

5. The template according to claim 3, wherein the second pattern is arranged on a region in which the first pattern in the transfer region is not formed.

6. The template according to claim 1, wherein
the first pattern and the second pattern have a convex structure on the principal surface of the template substrate, and
when the transfer is performed, the second pattern arranged on the transfer region is removed.

7. The template according to claim 1, wherein the second pattern is arranged on a region in which the first pattern in the transfer region is not formed.

8. The template according to claim 1, wherein
the first pattern is a line-and-space pattern,
the second pattern in the transfer region is formed so as to be embedded in the line-and-space pattern, and
when the transfer is performed, a portion of the second pattern in the transfer region which is embedded between line patterns configuring the line-and-space pattern is removed.

9. A manufacturing method of a template, comprising:
coating a template substrate including a transfer region on which a first pattern to be transferred to a processing target is arranged and a non-transfer region surrounding the transfer region with a resist;
drawing the pattern on the resist with an electron beam such that the first pattern is arranged on the transfer region, and a second pattern used to measure deviation of a pattern formed on the template substrate from a design position is arranged on at least the transfer region to form a resist pattern;
etching the template substrate using the resist pattern as a mask to form the first pattern and the second pattern;
measuring positional deviation of the first pattern on the template substrate from a design position using the second pattern; and
removing the second pattern.

10. The manufacturing method of the template according to claim 9, wherein
the forming of the resist pattern includes forming the resist pattern such that arrangement positions of the first pattern and the second pattern are opened,
the forming of the first pattern and the second pattern includes forming the first pattern and the second pattern having a concave shape on the template substrate, and
the removing of the second pattern includes embedding a embedded layer in the second pattern having the concave shape.

11. The manufacturing method of the template according to claim 10, wherein the embedded layer has a refractive index different from the template substrate.

12. The manufacturing method of the template according to claim 9, wherein the forming of the resist pattern includes forming the resist pattern such that the second pattern and the first pattern do not overlap in the transfer region.

13. The manufacturing method of the template according to claim 9, wherein
the forming of the resist pattern includes forming the resist pattern such that the resist remains on arrangement positions of the first pattern and the second pattern,
the forming of the first pattern and the second pattern includes forming the first pattern and the second pattern having a convex shape on the template substrate, and
the removing of the second pattern includes removing the second pattern by etching.

14. The manufacturing method of the template according to claim 9, wherein
the forming of the resist pattern includes forming a line-and-space pattern as the first pattern and forming the second pattern to be formed on the transfer region to be embedded in the line-and-space pattern, and
the removing of the second pattern includes removing a portion of the second pattern in the transfer region which is embedded between line patterns configuring the line-and-space pattern.

15. The manufacturing method of the template according to claim 14, wherein
the removing of the second pattern includes etching a portion embedded between the line patterns by a focused ion beam, or exciting an etching gas by a focused ion beam or an electron beam and selectively etching a portion embedded between the line patterns.

16. The manufacturing method of the template according to claim 9, wherein the second pattern has an optically recognizable size.

17. A position measuring method in a template in which a transfer region on which a first pattern to be transferred to a processing target is arranged and a non-transfer region surrounding the transfer region are formed on a principal surface of a template substrate, and a second pattern used to measure deviation of a pattern formed on the template substrate from a design position is arranged on the transfer region and the non-transfer region, the method comprising:
measuring a first positional deviation amount which is deviation of the second pattern of the non-transfer region from the design position;
measuring a second positional deviation amount which is deviation of the second pattern of the transfer region from the design position.

18. The position measuring method in the template according to claim 17, wherein the measurement of the first positional deviation amount and the measurement of the second positional deviation amount are simultaneously performed.

19. The position measuring method in the template according to claim 17, further comprising:
determining, after the measurement of the first positional deviation amount and before the measurement of the second positional deviation amount, whether or not the first positional deviation amount is within an allowable range; and
determining, after the measurement of the second positional deviation amount, whether or not the second positional deviation amount is within an allowable range.

20. The position measuring method in the template according to claim 19, wherein in the determination of the first positional deviation amount, when it is determined that the first positional deviation amount is within the allowable range, the measurement of the second positional deviation amount is performed, but when it is determined that the first positional deviation amount is not within the allowable range, the measurement of the second positional deviation amount is not performed.
